(19) United States
(12) Patent Application Publication
(10) Pub. No.: US 2026/0036543 A1
(43) Pub. Date: Feb. 5, 2026

(54) THRESHOLD VOLTAGE ADJUSTABLE TRANSISTOR USING INTERFACIAL DIPOLE LAYER

(71) Applicant: International Business Machines Corporation, Armonk, NY (US)

(72) Inventors: Takashi Ando, Eastchester, NY (US); Sufi Zafar, Briarcliff Manor, NY (US)

(21) Appl. No.: 18/788,226

(22) Filed: Jul. 30, 2024

(51) Int. Cl. G01N 27/414; H01L 27/088; H01L 29/06

(52) U.S. Cl. CPC G01N 27/4145; H10D 62/10; H10D 84/83

(57) ABSTRACT

Embodiments relate to threshold voltage adjustable transistor using an interfacial dipole layer. A semiconductor structure includes a transistor having source/drain regions coupled to a channel region and a gate structure formed on the channel region. The gate structure includes a second layer stacked on a first layer, and an interfacial layer is between the first and second layers, the interfacial layer including a group 2A element or a group 3B element. A biomolecule layer formed on top of the gate structure.

### BACKGROUND

The present invention generally relates to fabrication methods and resulting structures for integrated circuits, and more specifically, to fabrication methods and resulting structures configured and arranged for a threshold voltage (Vt) adjustable transistor (biosensor) using an interfacial dipole layer.

A metal-oxide-semiconductor field-effect transistor (MOSFET) is a transistor used for amplifying or switching electronic signals. The MOSFET has a source, a drain, a channel, and a gate electrode. The gate electrode is electrically insulated from the main semiconductor n-channel or p-channel by a thin layer of insulating material, for example, silicon dioxide, which makes the operation voltages of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The threshold voltage (Vt) of a transistor is the voltage level that must be achieved between the gate and the substrate in order to turn the transistor on. More specifically, when a voltage greater than Vt is applied to the transistor gate, the transistor is turned on, and current flows from the transistor's source through the channel to the drain. When the voltage at the gate is less than Vt, the switch is off, and current does not flow through the transistor.

### SUMMARY

Embodiments of the present invention are directed to a threshold voltage (Vt) adjustable transistor biosensor using an interfacial dipole layer. A semiconductor structure includes a transistor having source/drain regions coupled to a channel region and a gate structure formed on the channel region. The gate structure includes a second layer stacked on a first layer, and an interfacial layer is between the first and second layers, the interfacial layer including a group 2A element or a group 3B element. A biomolecule layer is formed on top of the gate structure.

According to one or more embodiments, a semiconductor structure includes a transistor having source/drain regions coupled to a channel region and a gate structure formed on the channel region. The gate structure includes a second layer stacked on a first layer, and an interfacial layer is between the first and second layers, the interfacial layer including aluminum or titanium. A biomolecule layer is formed on top of the gate structure.

According to one or more embodiments, a method for a transistor as a biosensor is provided. The method includes providing a biomolecule layer on the transistor. The transistor includes source/drain regions coupled to a channel region and a gate structure formed on the channel region. The gate structure includes a second layer stacked on a first layer, the biomolecule layer being formed on the second layer. An interfacial layer is between the first and second layers, the interfacial layer being configured to decrease or increase a threshold voltage of the transistor. The method includes applying a solution on the second layer.

Other embodiments of the present invention implement features of the above-described methods in structures/devices.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a cross-sectional view of a portion of semiconductor structure according to embodiments of the invention;

FIG. 2 depicts a cross-sectional view of a portion of semiconductor structure according to embodiments of the invention;

FIG. 3 depicts a cross-sectional view of a portion of semiconductor structure according to embodiments of the invention;

FIG. 4 depicts a cross-sectional view of a portion of semiconductor structure according to embodiments of the invention;

FIG. 5 depicts a cross-sectional view of a portion of semiconductor structure according to embodiments of the invention; and

FIG. 6 depicts a flowchart of a method for a transistor biosensor according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Ion-sensitive field-effect transistors (ISFETs) have emerged as a promising platform for manufacturing biosensors because of their miniaturized form-factor, low power consumption, high sensitivity, and feasibility for monolithic integration with other device and circuit components on the chip.

Generally, in a biosensor, the solution is in contact with gate dielectric sensing surface, a reference electrode applies gate voltage to solution (Vₛₒₗ), and drain current (I_{d}) is the sensing signal for characterizing the analyte. As a biosensor, the threshold voltage (Vt) of the FET sensor depends on the analyte to be detected and the pH (potential of hydrogen) of the test solution. In other words, the threshold voltage is not fixed by the fabrication process of the FET sensor (i.e., biosensor) but depends on the diagnostic application. An analyte is the specimen extracted for analysis from a portion or sample using a specific extraction protocol. The analyte is a chemical substance that is the subject of chemical analysis, and the analyte can be in the test solution. Analyte and test solution may be utilized interchangeably.

Post fabrication, the FET sensor is functionalized by attaching a biomolecule or biolayer to its sensing surface that preferentially binds target analytes. Different biolayers are attached for detecting different analytes. These biolayers are charged and therefore modify the threshold voltage, and the net charge on a biolayer depends on its composition. Also, the threshold voltage is (concurrently) impacted by the pH of the test solution in contact with the sensing surface of the FET.

According to one or more embodiments, the present disclosure provides a threshold voltage adjustable transistor (biosensor) using an interfacial dipole layer. The threshold voltage of the FET is adjusted via the amount of dipole forming elements at the interface (SiO₂/HfO₂ interface) of two dielectric layers of the gate depending on the pH of the solution, in order to adjust the threshold voltage to low values (e.g., less than (<) 0.2V). Although interface dipoles can adjust the threshold voltage for a non-electrode structure, the present disclosure provides such a structure in conjunction with a biosensing structure according to one or more embodiments.

FET biosensors can be used for measuring different analytes (e.g., ions, proteins, DNA, virus, etc.) from test mediums such as sweat (pH approximately (˜) 6-5), saliva (pH˜5-6.7), blood (pH˜7.4), etc. For portable sensing applications, it is beneficial that the threshold voltage is low (e.g., <0.2V). Because the threshold voltage of the FET sensor can be shifted by the biolayer and the test solution pH, one or more embodiments disclose tuning the FET sensor threshold during the fabrication process such that the low use voltage requirements are met for the targeted diagnostic application. According to one or more embodiments, a different dipole layer can be utilized to increase the threshold voltage of the biosensor to a higher voltage in applications where the biolayer and the test solution pH have decreased the threshold voltage.

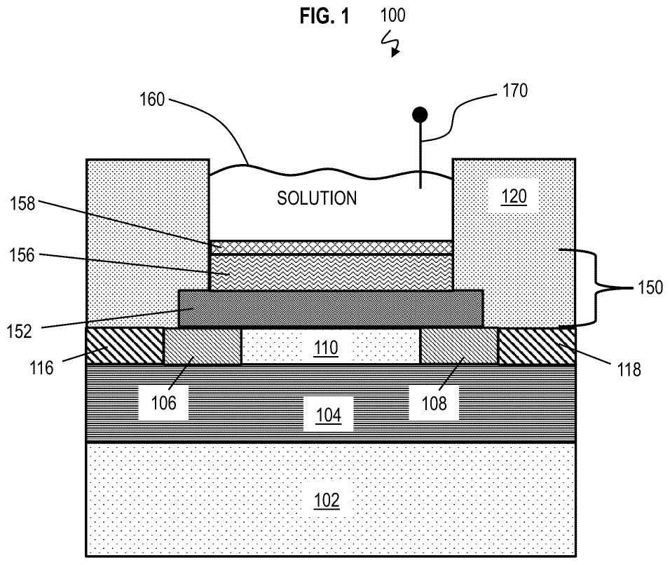

Turning now to a more detailed description of aspects of the present invention, FIG. 1 depicts a cross-sectional view of a portion of an FET biosensor 100 according to one or more embodiments of the invention. Standard semiconductor fabrication techniques can be utilized to fabricate FET biosensor 100 as understood by one of ordinary skill in the art. Any suitable deposition techniques and etching techniques can be utilized herein.

The FET biosensor 100 includes a channel region 110 formed on a substrate 102. The substrate 102 and the channel region 110 can be substantially pure silicon or other semiconductor materials. An intervening layer of a buried oxide layer 104 may be formed between the substrate 102 and the channel region 110. Source and drain regions can be formed on either sides of the channel region 110 as source region 106 and drain region 108. The source and drain regions can be heavily doped silicon material formed by doping techniques known in the art. Depending on the type of transistor, the source and drain regions can be doped with p-type dopants or n-type dopants. A source contact 116 is formed adjacent to the source region 106, and a drain contact 118 is formed adjacent to the drain region 108. Example metals utilized to form the source/drain contacts may include aluminum (Al), platinum (Pt), gold (Au), tungsten (W), titanium (Ti), or any combination thereof. It should be appreciated that a silicide may be formed between the contact metal and the semiconductor material of the source/drains.

A gate structure 150 is formed on the channel region 110. A portion of the gate structure may be formed on the source region 106 and drain region 108. The gate structure 150 includes a first dielectric layer 152 formed on the channel region 110, and a second dielectric layer 156 formed on the first dielectric layer 152. The second dielectric layer 156 is a sensing surface. A fill layer 120 may be formed on the source contact 116, drain contact 118, and first dielectric layer 152 in order to contain a test solution 160. The fill layer 120 can be a low-k dielectric material, ultra-low-k dielectric material, etc. The fill layer 120 can be an oxide. A gate electrode or reference electrode 170 is applied to the test solution 160 to provide a gate voltage (V solution (Vₛₒₗ)) to the test solution 160. A biomolecule layer 158 (i.e., biolayer) can be applied to and/or coated on the gate structure 150 in accordance with the type of analyte in the test solution 160 being tested. The biomolecule layer 158 can be negatively or positively charged. The biomolecule can be a negatively charged DNA strand. The biomolecule layer 158 can be positively charged lysine. Other examples of the biomolecule layer 158 include (3-Aminopropyl) triethoxysilane (APTES) terminated with amine or carboxyl groups, APTES or phosphonic acid terminated biotin, thiolated biotin, Bovine serum albumin (BSA), etc. The first dielectric layer 152 may be silicon dioxide (SiO₂), and the second dielectric layer 156 may be hafnium oxide (HfO₂). Particularly, the biomolecule layer 158 is applied to the second dielectric layer 156 (e.g., HfO₂). As an example of threshold voltage dependence on test solution, the threshold voltage has been observed to increase with increasing pH for a HfO₂ FET sensor. As an example of threshold voltage dependence on a negatively charged biolayer, the threshold voltage has been observed to increase when the HfO₂ sensing surface is coated with a biolayer formed of negatively charged 25 nucleotide long DNA strands. As an example of threshold voltage dependence on a positively charged biolayer, the threshold voltage has been observed to decrease when the HfO₂ sensing surface is coated with a biolayer formed of positively charged lysine.

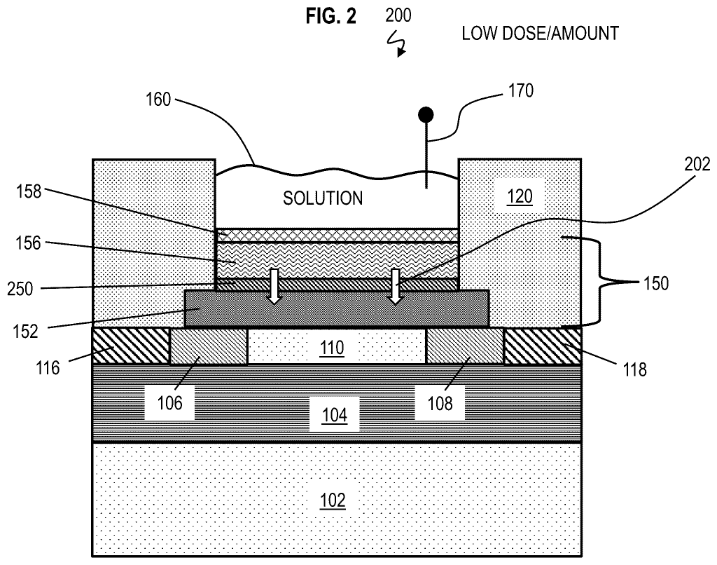

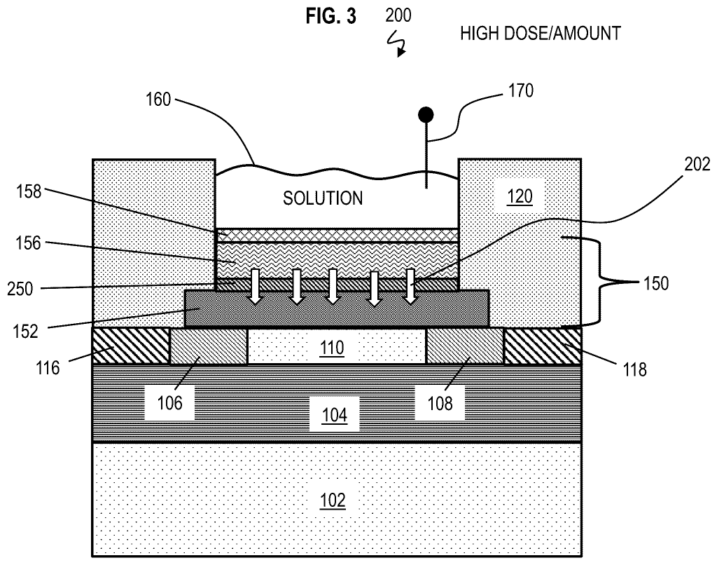

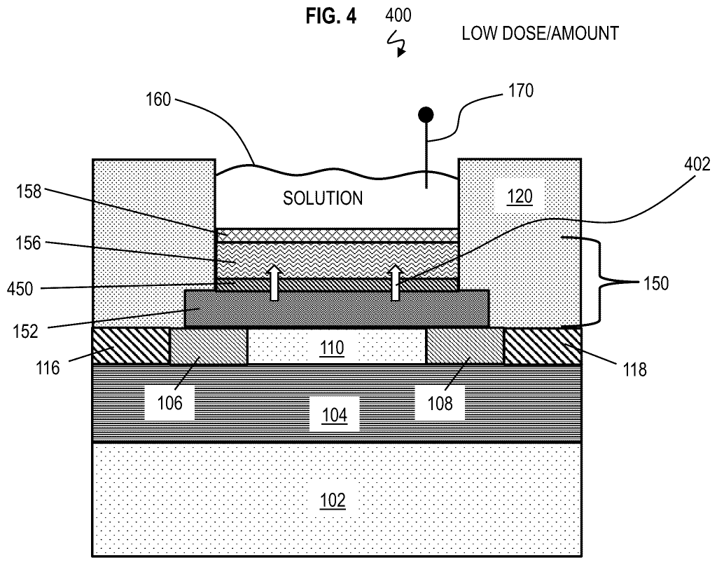

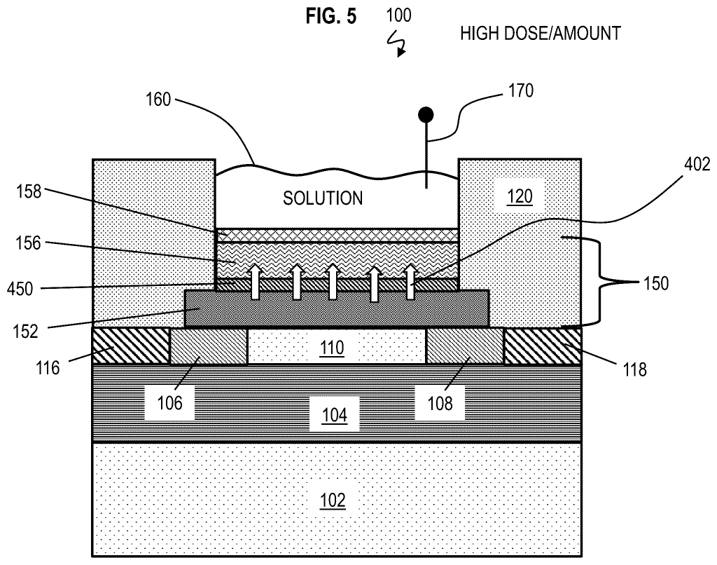

FIG. 1 illustrates an undoped transistor in which a dipole interfacial layer is not present between the first dielectric layer 152 and the second dielectric layer 156. As discussed herein, an interfacial dipole layer 250 depicted in an FET biosensor 200 of FIGS. 2 and 3 or an interfacial dipole layer 450 depicted in an FET biosensor 400 of FIGS. 4 and 5 can be formed as an intervening layer between the first dielectric layer 152 and the second dielectric layer 156, in order to shift the threshold voltage as desired. It is noted that the interfacial dipole layers 250 and 450 may be a monolayer thick or a few angstroms thick. The interfacial dipole layers 250 and 450 are not intended to be drawn to scale but are depicted with an exaggerated size for visual recognition and illustration.

Now turning to FIG. 2, the FET biosensor 200 is analogous to the FET biosensor 100 except the interfacial dipole layer 250 is formed as an intervening layer between the first dielectric layer 152 and the second dielectric layer 156, in order to shift the threshold voltage of the FET. The interfacial dipole layer 250 includes group 2A elements and/or group 3B elements to decrease the threshold voltage of the FET biosensor 200. The elements are doped at the SiO₂/HfO₂ interface for sensing a middle pH solution and a high pH solution. A higher dose/amount of the interfacial dipole layer 250 is utilized for a high pH solution (and/or a more negatively charged biomolecule layer 158) as compared to a lower dose/amount of the interfacial dipole layer 250 being used for a middle pH solution (and/or a less negatively charged biomolecule layer 158). The high dose/amount of the dipoles of the interfacial dipole layer 250 can be implemented as a thicker interfacial dipole layer 250, a higher density per square inch (area) of atoms of the elements, etc., as compared to a low dose/amount of dipoles of the interfacial dipole layer 250. Arrows 202 indicate that the electric dipole direction is pointing downward, and the number of arrows 202 represents the intensity/amount of the interfacial dipole layer (or dipoles).

The group 2A elements are also called alkali earth metals, which include the elements beryllium (Be), magnesium (Mg), calcium (Ca), strontium (Sr), barium (Ba), and radium (Ra). The group 3B elements include the elements scandium (Sc), yttrium (Y), lanthanum (La), and actinium (Ac).

FIG. 2 represents the FET biosensor 200 with a low dose/amount of material for the interfacial dipole layer 250 (e.g., for a middle pH solution), while FIG. 3 represents the FET biosensor 200 with a high dose/amount of material for the interfacial dipole layer 250 (e.g., for a high pH solution).

In FIG. 2, the low dose/amount of the dipoles of the interfacial dipole layer 250 can be implemented as having a (low) predefined thickness for the interfacial dipole layer 250 and/or having a (low) predefined density per square inch (area) of atoms of the group 2A and 3B elements. For example, the interfacial dipole layer thickness can be about 3 to 10 angstroms (Å) for a low dose condition.

In FIG. 3, the high dose/amount of the dipoles of the interfacial dipole layer 250 can be implemented as having a (high) predefined thickness for the interfacial dipole layer 250 and/or having a (high) predefined density per square inch (area) of atoms of the group 2A and 3B elements. For example, the interfacial dipole layer thickness can be 10 to 30 (Å) for a high dose condition. The high dose/amount of the dipoles of the interfacial dipole layer 250 in FIG. 3 is greater than the low dose/amount of dipoles of the interfacial dipole layer 250 in FIG. 2. FIG. 3 depicts a greater number of (dipole) arrows 202 than in FIG. 2, which indicate a greater intensity/amount of the interfacial dipole layer (or dipoles) than in FIG. 2.

Now turning to FIG. 4, the FET biosensor 400 is analogous to the FET biosensor 100 except the interfacial dipole layer 450 is formed as an intervening layer between the first dielectric layer 152 and the second dielectric layer 156, in order to shift the threshold voltage of the FET. The interfacial dipole layer 450 includes aluminum (Al) and/or titanium (Ti) to increase the threshold voltage of the FET biosensor 400. The elements are doped at the SiO₂/HfO₂ interface for sensing a low pH solution and a middle pH solution. A higher dose/amount of the interfacial dipole layer 450 is utilized for a low pH solution (and/or a more positively charged biomolecule layer 158) as compared to a lower dose/amount of the interfacial dipole layer 450 being used for a middle pH solution (and/or a less positively charged biomolecule layer 158). The high dose/amount of the dipoles of the interfacial dipole layer 450 can be implemented as a thicker interfacial dipole layer 450, a higher density per square inch (area) of atoms of the elements, etc., as compared to a low dose/amount of dipoles of the interfacial dipole layer 450. Arrows 402 indicate that the dipole direction is pointing upward, and the number of arrows 402 represents the intensity/amount of the interfacial dipole layer (or dipoles).

FIG. 4 represents the FET biosensor 400 with a low dose/amount of material for the interfacial dipole layer 250 (e.g., for a middle pH solution), while FIG. 5 represents the FET biosensor 400 with a high dose/amount of material for the interfacial dipole layer 250 (e.g., for a low pH solution).

In FIG. 4, the low dose/amount of the dipoles of the interfacial dipole layer 450 can be implemented as having a (low) predefined thickness for the interfacial dipole layer 450 and/or having a (low) predefined density per square inch (area) of atoms of the aluminum and/or titanium elements. For example, the interfacial dipole layer thickness can be 3 to 10 (Å) for a low dose condition.

In FIG. 5, the high dose/amount of the dipoles of the interfacial dipole layer 450 can be implemented as having a (high) predefined thickness for the interfacial dipole layer 450 and/or having a (high) predefined density per square inch (area) of atoms of the of aluminum and/or titanium elements. For example, the interfacial dipole layer thickness can be 10 to 30 (Å) for a high dose condition. The high dose/amount of the dipoles of the interfacial dipole layer 450 in FIG. 5 is greater than the low dose/amount of dipoles of the interfacial dipole layer 450 in FIG. 4. FIG. 5 depicts a greater number of (dipole) arrows 202 than in FIG. 4, which indicate a greater intensity/amount of the interfacial dipole layer (or dipoles) than in FIG. 4.

According to one or more embodiments, a semiconductor structure includes a transistor (e.g. FET biosensor 200 and/or FET biosensor 400) source/drain regions (e.g., source region 106 and drain region 108) coupled to a channel region 110, a gate structure 150 formed on the channel region 110, where the gate structure 150 includes a second dielectric layer 156 stacked on a first dielectric layer 152, where an interfacial dipole layer 250 (or interfacial dipole layer 450) is between the first and second layers, the interfacial dipole layer 250 comprising group 2A elements and/or group 3B elements or e.g., the interfacial dipole layer 450 comprising aluminum and/or titanium). A biomolecule layer 158 is formed on top of the gate structure 150.

Further, the interfacial layer shifts a threshold voltage of the transistor. Threshold voltage of the transistor is decreased in accordance with (an increase in) a density of the interfacial layer (e.g., interfacial dipole layer 250). Threshold voltage of the transistor is increased in accordance with (an increase in) a density of the interfacial layer (e.g., interfacial dipole layer 450). The interfacial layer is a dipole layer. In FIGS. 2 and 3, the interfacial layer comprises downward pointing electric dipoles (e.g., arrows 202) relative to the channel region 110. In FIGS. 4 and 5, the interfacial layer comprises upward pointing electric dipoles (e.g., arrows 402) relative to the channel region 110.

Additionally, the first layer comprises a first dielectric layer and the second layer comprises a second dielectric layer having a greater dielectric constant k than the first dielectric layer. The first layer comprises silicon dioxide and the second layer comprises hafnium dioxide. A solution 160 is on the biomolecule layer 158.

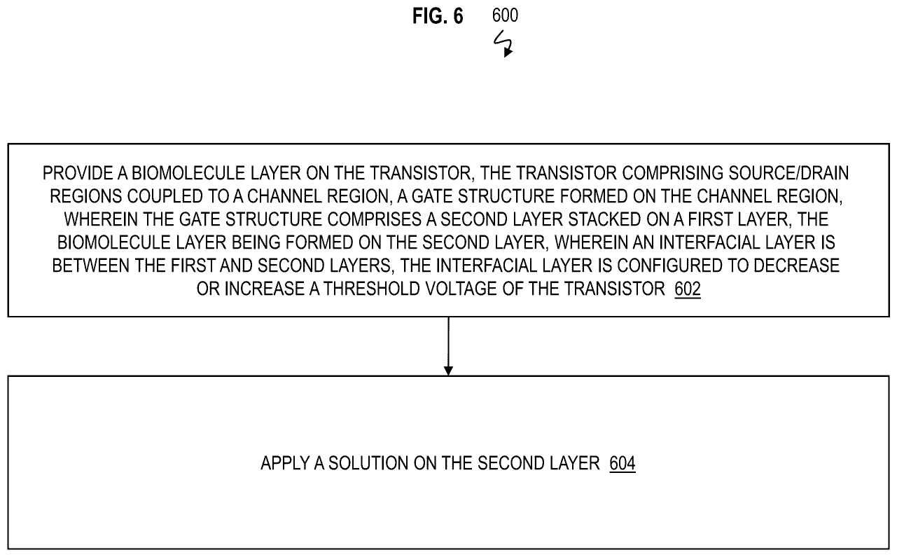

FIG. 6 is a flowchart of a method 600 for a transistor as a biosensor according to one or more embodiments. The transistor has an adjustable threshold voltage according to the desired biosensor application. Reference can be made to any of the figures discussed herein.

At block 602, the method 600 includes providing a biomolecule layer 158 on the transistor (e.g., FET biosensor 200 or FET biosensor 400), the transistor comprising source/drain regions coupled to a channel region 110, a gate structure 150 formed on the channel region 110, where the gate structure 150 comprises a second layer stacked on a first layer, the biomolecule layer 158 being formed on the second layer, where an interfacial layer (e.g., interfacial dipole layer 250 or interfacial dipole layer 450) is between the first and second layers, the interfacial layer is configured to decrease or increase a threshold voltage of the transistor. At block 604, the method includes applying a solution 160 on the second layer.

A degree of decreasing or increasing the threshold voltage of the transistor is in accordance with a density of the interfacial layer.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprises:
a transistor comprising source/drain regions coupled to a channel region, a gate structure formed on the channel region, wherein the gate structure comprises a second layer stacked on a first layer, wherein an interfacial layer is between the first and second layers, the interfacial layer comprising a group 2A element or a group 3B element; and
a biomolecule layer formed on top of the gate structure.

2. The semiconductor structure of claim 1, wherein the interfacial layer is structured to shift a threshold voltage of the transistor.

3. The semiconductor structure of claim 1, wherein a threshold voltage of the transistor is decreased in accordance with a density of the interfacial layer.

4. The semiconductor structure of claim 1, wherein the interfacial layer is a dipole layer.

5. The semiconductor structure of claim 1, wherein the interfacial layer comprises downward pointing dipoles relative to the channel region.

6. The semiconductor structure of claim 1, wherein the first layer comprises a first dielectric layer and the second layer comprises a second dielectric layer having a greater dielectric constant than the first dielectric layer.

7. The semiconductor structure of claim 1, wherein the first layer comprises silicon dioxide and the second layer comprises hafnium dioxide.

8. The semiconductor structure of claim 1, wherein a solution is on the biomolecule layer.

9. A semiconductor structure comprises:
a transistor comprising source/drain regions coupled to a channel region, a gate structure formed on the channel region, wherein the gate structure comprises a second layer stacked on a first layer, wherein an interfacial layer is between the first and second layers, the interfacial layer comprising aluminum or titanium; and
a biomolecule layer formed on top of the gate structure.

10. The semiconductor structure of claim 9, wherein the interfacial layer is structured to shift a threshold voltage of the transistor.

11. The semiconductor structure of claim 9, wherein a threshold voltage of the transistor is increased in accordance with a density of the interfacial layer.

12. The semiconductor structure of claim 9, wherein the interfacial layer is a dipole layer.

13. The semiconductor structure of claim 9, wherein the interfacial layer comprises upward pointing dipoles relative to the channel region.

14. The semiconductor structure of claim 9, wherein the first layer comprises a first dielectric layer and the second layer comprises a second dielectric layer having a greater dielectric constant than the first dielectric layer.

15. The semiconductor structure of claim 9, wherein the first layer comprises silicon dioxide and the second layer comprises hafnium dioxide.

16. The semiconductor structure of claim 9, wherein a solution is on the biomolecule layer.

17. A method for a transistor as a biosensor, the method comprising:
providing a biomolecule layer on the transistor, the transistor comprising source/drain regions coupled to a channel region, a gate structure formed on the channel region, wherein the gate structure comprises a second layer stacked on a first layer, the biomolecule layer being formed on the second layer, wherein an interfacial layer is between the first and second layers, the interfacial layer being configured to decrease or increase a threshold voltage of the transistor; and
applying a solution on the second layer.

18. The method of claim 17, wherein:
the interfacial layer comprises a group 2A element or a group 3B element to decrease the threshold voltage of the transistor; or
the interfacial layer comprises aluminum or titanium to increase the threshold voltage of the transistor.

19. The method of claim 17, wherein a degree of decreasing or increasing the threshold voltage of the transistor is in accordance with a density of the interfacial layer.

20. The method of claim 17, wherein the first layer comprises a first dielectric layer and the second layer comprises a second dielectric layer having a greater dielectric constant than the first dielectric layer.
